(19) United States
(12) Patent Application Publication
(10) Pub. No.: US 2009/0166664 A1
(43) Pub. Date: Jul. 2, 2009

(54) HIGH POWER LIGHT EMITTING DIODE PACKAGE AND MANUFACTURING METHOD THEREOF

(75) Inventors: Jung Kyu Park, Seoul (KR); Kun Yoo Ko, Hwaseong (KR); Young Sam Park, Seoul (KR); Seung Hwan Chol, Suwon (KR); Il Ku Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/327,552

(22) Filed: Dec. 3, 2008

(30) Foreign Application Priority Data
Dec. 28, 2007 (KR) 10-2007-0140549
Oct. 2, 2008 (KR) 10-2008-0097213

(51) Int. Cl. H01L 33/00; H01L 21/24

(52) U.S. Cl. 257/99; 438/26; 257/E21.154; 257/E33.002

(57) ABSTRACT

There is provided a high power LED package and a method of manufacturing the same. The method includes: forming at least one chip mounting part and at least one through hole in a metal plate; forming an insulating layer of a predetermined thickness on an entire outer surface of the metal plate; forming an electrode part to be electrically connected to a light emitting chip mounted on the chip mounting part; and cutting the metal plate along a trimming line to separate the package. The LED package is free from thermal impact resulting from different thermal coefficients among components, thus ensuring stable heat radiation characteristics in a high temperature atmosphere. Also, the LED package is minimized in optical loss to improve optical characteristics. In addition, the LED package is simplified in a manufacturing and assembly process and thus can be manufactured in mass production at a lower cost.

### CROSS-REFERENCE TO RELATED APPLICATIONS

This application claims the priorities of Korean Patent Application Nos. 2007-0140549 filed on Dec. 28, 2007 and 2008-0097213 filed on Oct. 2, 2008, in the Korean Intellectual Property Office, the disclosures of which are incorporated herein by reference.

### BACKGROUND OF THE INVENTION

1. Field of the Invention

The present invention relates to a high power light emitting diode package and a manufacturing method of the same.

2. Description of the Related Art

In general, a light emitting diode (LED) is a semiconductor device emitting light when current flows, and a PN junction diode formed of a GaAs or GaN optical semiconductor which converts an electrical energy into a photonic energy.

The light emitted from this LED ranges from red light spectrum (630 nm to 700 nm) to blue-violet light spectrum (400 nm), thus encompassing blue, green and white light spectrums. The LED is lower in power consumption, higher in efficiency and longer in operational time than a conventional light source such as an incandescent bulb and fluorescent light, thus facing a rising demand.

Recently, the LED has seen its application gradually broadening from compact lightings for mobile terminals to indoor and outdoor general lightings, car lightings, and backlights for large-sized liquid crystal displays (LCDs).

Accordingly, in proportion to intensity of light generated when current is supplied, power applied to a light emitting chip, i.e., a light emitting source is increased. The high power LED with considerable power consumption generally adopts a heat radiation structure for preventing the light emitting chip and the package itself from being degraded by heat resulting from light emission.

FIG. 1A is a perspective cross-sectional view illustrating a central portion of a conventional high power LED package, and FIG. 2B is a cross-sectional view illustrating a conventional high power LED package assembled on a substrate. As shown, the LED package 10 includes a light emitting chip 11 as a light emitting source and a heat radiator 12 having the light emitting chip 11 on a central portion of a top surface thereof.

The light emitting chip 11 is connected to an external power source and electrically connected to a plurality of lead frames 14 by a plurality of metal wires 13 to enable current to be supplied thereto.

The heat radiator 12 outwardly radiates and cools heat generated when the light emitting chip 11 emits light. The heat radiator 12 is disposed on a substrate 19 by an adhesive 12a made of a highly conductive material.

The lead frames 14 are integrally formed on a molding 15. The heat radiator 12 is inserted into an assembly hole 15a formed in a central portion of the molding part 15. Each of the lead frames 14 has one end exposed to the molding 15 to be wire-bonded to a wire 13. Also, the lead frame 14 has another end electrically connected to a pattern circuit 19a printed on the substrate 19 by pads 14a.

A lens 16 is disposed on a top surface of the molding 15 to broadly diffuse light generated by light emitted from the light emitting chip 11 outward. A void between the molding 15 and the lens 16 is filled with a filler 17 made of a transparent silicon resin to protect the light emitting chip 11 and the wire 13 and transmit the emitted light therethrough.

However, the conventional LED package 10 with this structure may be degraded in thermal characteristics since the molding part 15 made of polymer may be deteriorated at a high temperature. Besides, the LED package 10 may be ruined by repeated thermal impact due to big thermal coefficient differences between the lead frame 14 and the molding part 15.

Moreover, in the LED package 10, when the molding part 15 is injection-molded, the lead frame 14 has the one end exposed outward and the assembly hole 15a where the heat radiator 12 is inserted is formed on the central portion of the molding part. This entails manufacture of a precise mold, and complicates injection-molding and assembly processes, thereby increasing manufacturing costs.

### SUMMARY OF THE INVENTION

An aspect of the present invention provides a high power light emitting diode (LED) package which is free from thermal impact resulting from different thermal expansion coefficients among components to ensure stable heat radiation properties at a high temperature, minimized in optical loss to enhance optical properties and simplified in manufacturing and assembly processes to enable mass production at a lower cost, and a method of manufacturing the same.

According to an aspect of the present invention, there is provided a method of manufacturing a high-power light emitting diode package, the method including: forming at least one chip mounting part and at least one through hole in a metal plate; forming an insulating layer of a predetermined thickness on an entire outer surface of the metal plate; and forming an electrode part to be electrically connected to a light emitting chip mounted on the chip mounting part.

The forming at least one chip mounting part and at least one through hole may include forming the chip mounting part of a predetermined height by chemically etching or mechanically polishing a top surface of the metal plate and then forming the through hole in a lower portion of the top surface of the metal plate having a height smaller than a height of the chip mounting part.

The forming at least one chip mounting part and at least one through hole may include forming the through hole in a top surface of the metal plate and then forming the chip mounting part of a predetermined height by chemically etching or mechanically polishing the top surface of the metal plate.

The forming at least one chip mounting part and at least one through hole may include forming the chip mounting part of a predetermined depth by chemically etching or mechanically polishing a top surface of the metal plate and then forming the through hole in the top surface of the metal plate having a height greater than a height of the chip mounting part.

The forming at least one chip mounting part and at least one through hole may include forming the through hole in a top surface of the metal plate and then forming the chip mounting part of a predetermined depth by chemically etching or mechanically polishing the top surface of the metal plate.

The forming at least one chip mounting part and at least one through hole may include forming the chip mounting part on a top surface of the metal plate where the through hole is formed. The forming at least one chip mounting part and at least one through hole may include forming a trench of a predetermined depth by chemically etching or mechanically polishing a top surface of the metal plate to form the chip mounting part having an outer circumference defined by the trench.

The forming at least one chip mounting part and at least one through hole may include forming the through hole on a top surface of the metal plate and forming a trench of a predetermined depth by chemically etching or mechanically polishing the top surface of the metal plate to form the chip mounting part having an outer circumference defined by the trench.

The metal plate may be formed of an anodizable metal.

The metal plate may be formed of one of aluminum, aluminum alloy, magnesium, magnesium alloy, titanium, and titanium alloy.

The insulating layer may be formed by one of anodizing, plasma electrolyte oxidation, and dry oxidation.

The insulating layer may be formed of one of Al₂O₃, TiO₂, and MgO.

The forming an electrode part may include: forming a conductive via by filling or applying a conductive material in the through hole having the insulating layer applied on an inner circumferential surface thereof; forming external electrodes to connect to a top end and bottom end of the conductive vias exposed outward from the insulating layer, respectively; and electrically connecting the light emitting chip mounted on the chip mounting part to the external electrodes, respectively.

The forming an electrode part may include: forming a metal layer of at least a single layer structure on an entire outer surface of the insulating layer and forming a through via hole; forming external electrodes to connect to a top end and bottom end of conductive vias, respectively by partially removing the metal layer; and electrically connecting the light emitting chip mounted on the chip mounting part to the external electrodes, respectively.

The electrically connecting the light emitting chip to the external electrodes may include wire-bonding the light emitting chip mounted on the chip mounting part protruded to a predetermined height from a top surface of the metal plate to the external electrodes by metal wires.

The electrically connecting the light emitting chip to the external electrodes may include wire-bonding the light emitting chip mounted on the chip mounting part recessed to a predetermined depth from a top surface of the metal plate to the external electrodes by metal wires.

The electrically connecting the light emitting chip to the external electrodes may include flip-chip bonding the light emitting chip to the external electrodes extended to the chip mounting part.

The electrically connecting the light emitting chip to the external electrodes may include wire-bonding the light emitting chip to the external electrodes by a metal wire, the light emitting chip mounted on the chip mounting part having an outer circumference defined by a trench recessed to a predetermined height from a top surface of the metal plate.

The external electrodes may be formed by one of a process of printing and sintering a conductive paste, a process of metallizing and plating a surface of the insulating layer and a vacuum deposition process.

The method may further include forming an encapsulant containing a phosphor on a top surface of the chip mounting part to encapsulate the light emitting chip.

The forming an encapsulant may include forming a lens part or a molding part for protecting the light emitting chip, the encapsulant encapsulating the light emitting chip and a portion of the electrode part electrically connected to the light emitting chip from external environment.

The method may further include forming a lens part or a molding part on a top surface of the metal plate to protect the light emitting chip from external environment, the lens part or the molding part made of a transparent material.

The method may further include cutting the metal plate along a trimming line to separate the package.

The cutting the metal plate may include cutting the metal plate along the trimming line passing through a portion between one conductive via hole and another adjacent conductive via hole.

The chip mounting part may include a plurality of chip mounting parts, and the cutting the metal plate may include cutting the metal plate along the trimming line passing through a center of a conductive via hole formed between one of the chip mounting parts and another adjacent chip mounting part.

According to another aspect of the present invention, there is provided a high power light emitting diode package including: a heat radiator including a chip mounting part having at least one light emitting chip mounted thereon and at least one conductive via hole; an insulating layer formed with a predetermined thickness on an outer surface of the heat radiator; and an electrode part electrically connecting the conductive via hole and the light emitting chip.

The heat radiator may be formed of an anodizable metal.

The heat radiator may be formed of one of aluminum, aluminum alloy, magnesium, magnesium alloy, titanium, and titanium alloy.

The chip mounting part may include the chip mounting part may include one of a protrusion type chip mounting part protruded to a predetermined height from a top surface of the heat radiator, a recession type chip mounting part recessed to a predetermined depth from the top surface of the heat radiator, a substrate type chip mounting part disposed on the top surface of the heat radiator and a trench type chip mounting part recessed to a predetermined depth from the top surface of the heat radiator.

The insulating layer may be formed with a predetermined thickness on an outer surface of the heat radiator by one of anodizing, plasma electrolyte oxidation, and dry oxidation.

The insulating layer may be formed of one of Al₂O₃, TiO₂, and MgO.

The electrode part may include: a conductive via hole formed by filling or applying a conductive material in the through hole having the insulating layer applied on an inner circumferential surface thereof; external electrodes formed on the insulating layer to connect to a top end and bottom end of the conductive via hole, respectively; and a metal wire wire-bonding the light emitting diode chip to the external electrodes.

The electrode part may include: a conductive via hole formed by filling or applying a conductive material in the through hole having the insulating layer applied on an inner circumferential surface thereof; external electrodes formed on the insulating layer to connect to a top end and bottom end of the conductive via hole, respectively; and a solder ball flip-chip bonding the light emitting chip to the external electrodes.

The electrode part may include: a conductive via hole formed by filling or applying a conductive material in the through hole having the insulating layer applied on an inner circumferential surface thereof; external electrodes formed by partially removing a metal layer of at least a single layer structure applied on an entire outer surface of the insulating layer to connect to a top end and bottom end of the conductive via hole, respectively; and a metal wire wire-bonding the light emitting diode chip to the external electrodes.

The electrode part may include: a conductive via hole formed by filling or applying a conductive material in the through hole having the insulating layer applied on an inner circumferential surface thereof; external electrodes formed by partially removing a metal layer of at least a single layer structure applied on an entire outer surface of the insulating layer to connect to a top end and bottom end of the conductive via hole, respectively; and a solder ball flip-chip bonding the light emitting chip to the external electrodes.

The conductive via hole may be formed in one of an inner portion, a corner and an edge of the heat radiator.

The heat radiator may further include a lens part or a molding part formed of a transparent material to protect the light emitting chip from external environment.

The heat radiator may include: an encapsulant formed on the chip mounting part to encapsulate the light emitting chip; and a lens part or a molding part formed of a transparent material and protecting the light emitting chip, the encapsulant and a portion of the electrode part from external environment.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a perspective cross-sectional view illustrating a conventional high power light emitting diode (LED) package;

FIG. 1B is a cross-sectional view illustrating a conventional LED package assembled on a substrate;

FIGS. 2A to 2I are cross-sectional views illustrating a method of manufacturing a high power LED package according to an exemplary embodiment of the invention;

FIGS. 3A to 3H are perspective views illustrating a method of manufacturing a high power LED package according to an exemplary embodiment of the invention;

FIGS. 4A to 4C are procedural views illustrating a process of forming a recessed chip mounting part in a high power LED package according to an exemplary embodiment of the invention;

FIG. 5 is a procedural view illustrating a process of forming a substrate-type chip mounting part in a high power LED package according to an exemplary embodiment of the invention;

FIGS. 6A to 6C are a procedural view illustrating a process of forming a trench-type chip mounting part a high power LED package according to another exemplary embodiment of the invention;

FIGS. 7A to 7C illustrate a light emitting diode chip mounted by forming a metal layer in a high power LED package according to an exemplary embodiment of the invention;

FIG. 8 illustrates a light emitting diode chip mounted on a recessed chip mounting part in a high power LED package according to an exemplary embodiment of the invention;

FIG. 9 illustrates a light emitting diode chip mounted on a substrate-type chip mounting part in a high power LED package according to an exemplary embodiment of the invention;

FIG. 10 illustrates a light emitting diode chip mounted on a trench-type chip mounting part in a high power LED package according to another exemplary embodiment of the invention;

FIGS. 11A and 11B illustrate a heat radiator employed in a high power LED package according to an exemplary embodiment of the invention, in which FIG. 11A is a heat radiator having a conductive via hole formed in an inner portion thereof, and FIG. 11B is a heat radiator having a conductive via hole formed in an outer portion thereof.

FIG. 12 is a cross-sectional view illustrating a high power LED package according to an exemplary embodiment of the invention;

FIG. 13 is a cross-sectional view illustrating a high power LED package according to another exemplary embodiment of the invention;

FIG. 14 is a cross-sectional view illustrating a high power LED package according to still another exemplary embodiment of the invention;

FIG. 15 is a cross-sectional view illustrating a high power LED package according to a modified embodiment of the invention; and

FIG. 16 is a cross-sectional view illustrating a high power LED package according to another modified embodiment of the invention.

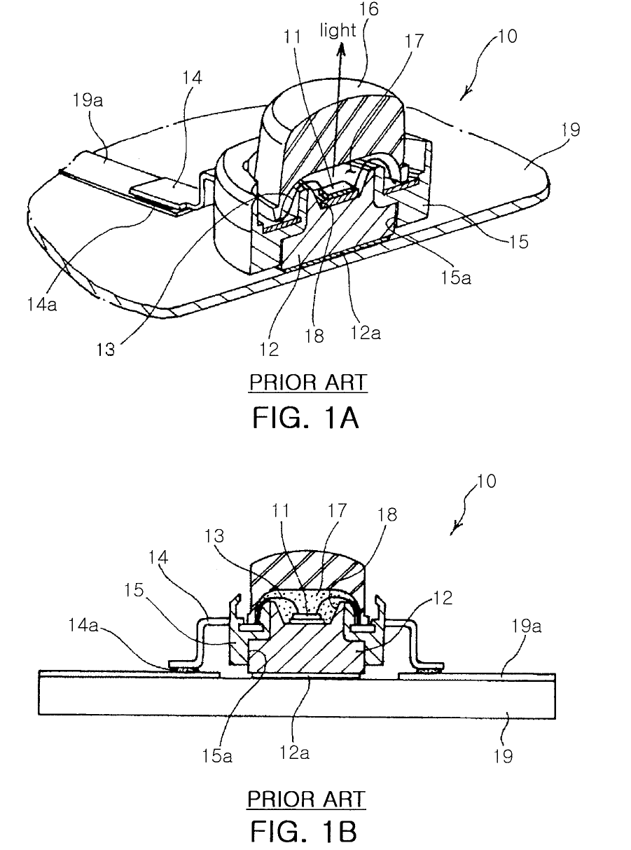

### DETAILED DESCRIPTION OF THE PREFERRED EMBODIMENT

Exemplary embodiments of the present invention will now be described in detail with reference to the accompanying drawings.

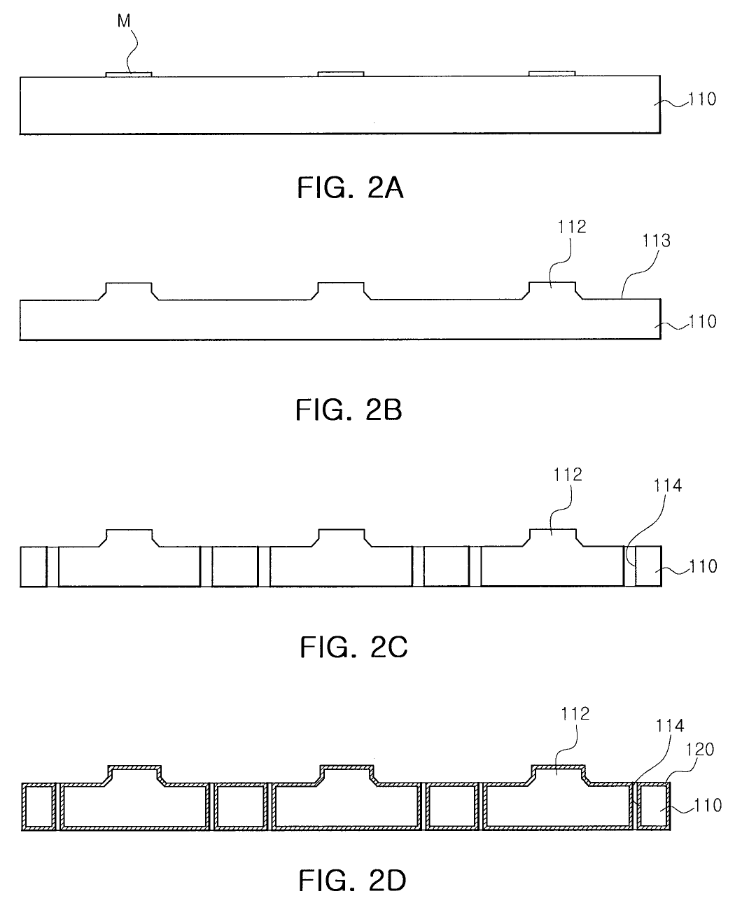

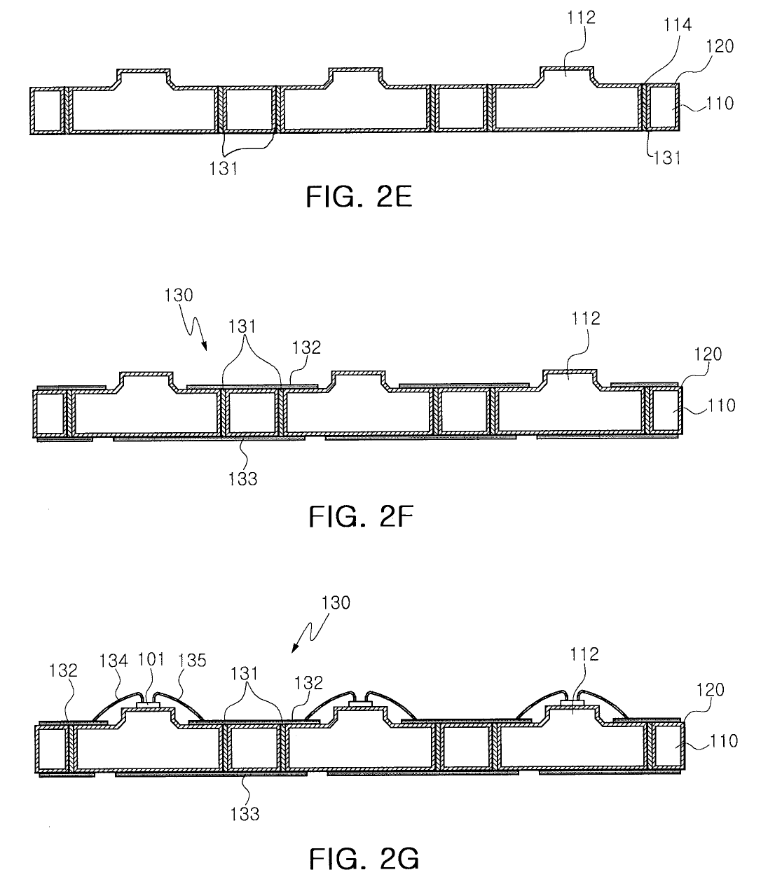

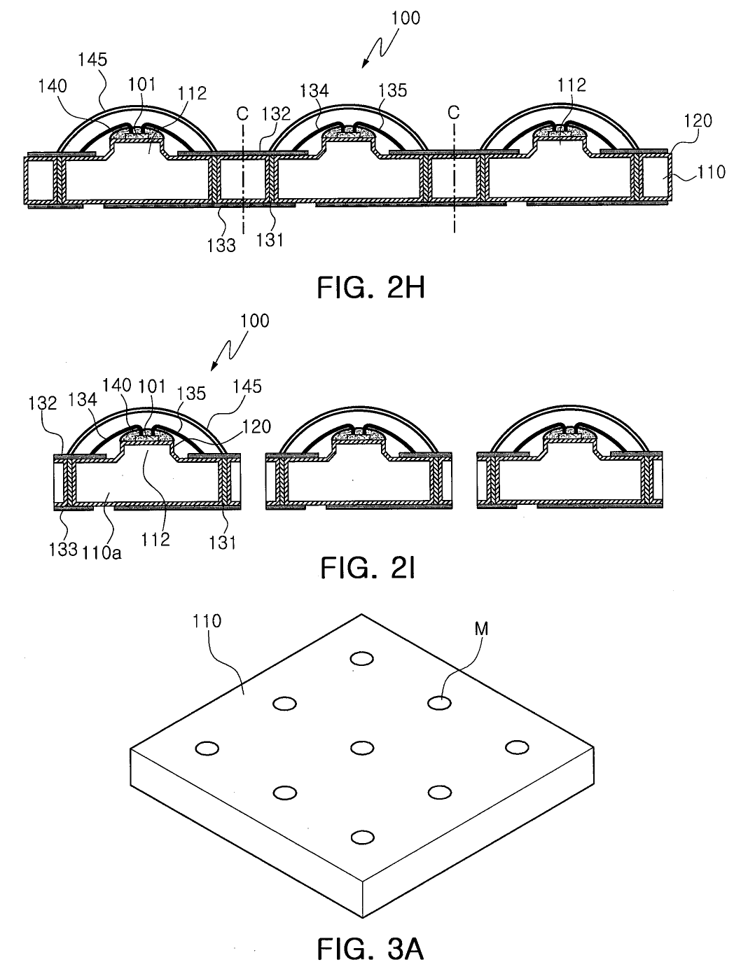

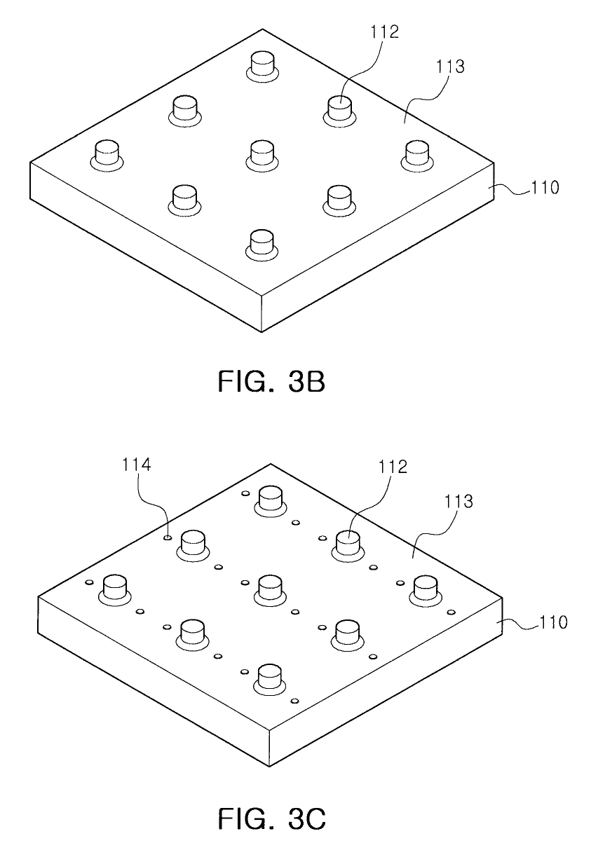

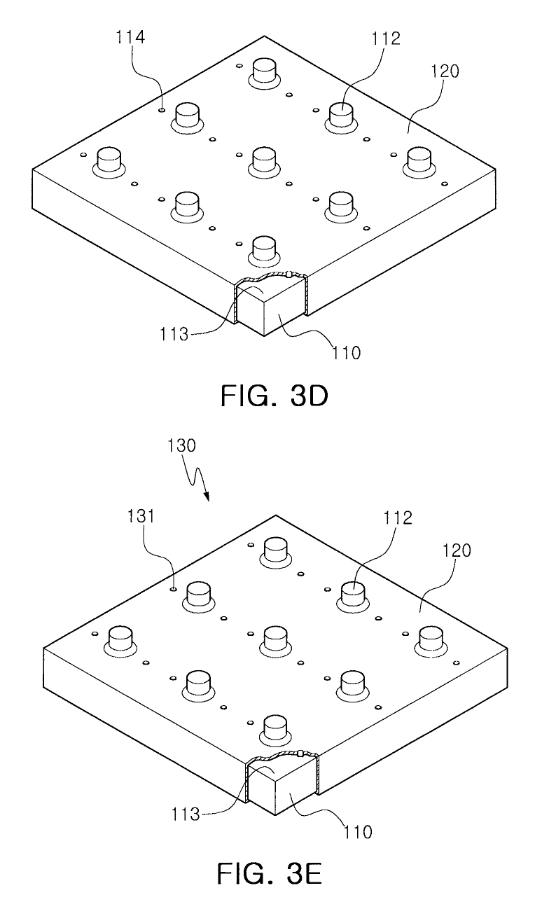

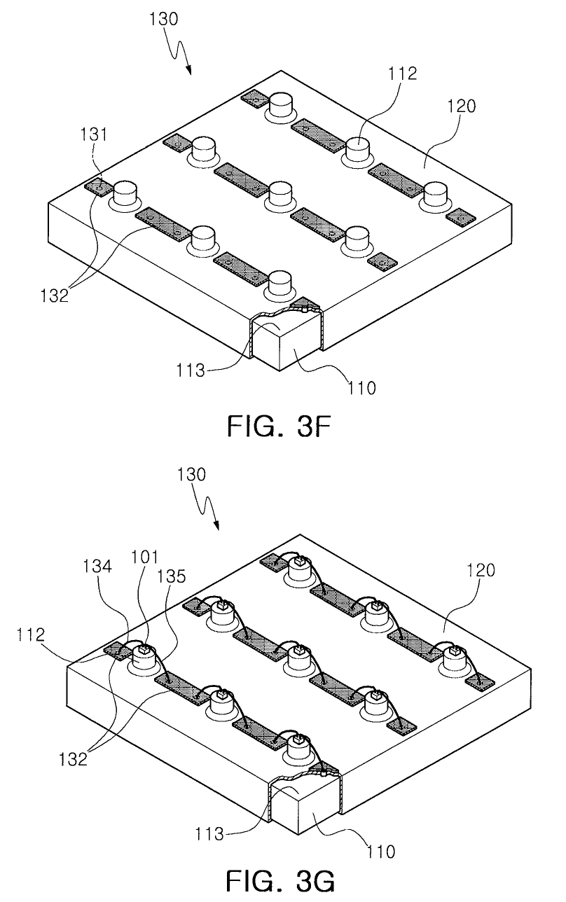

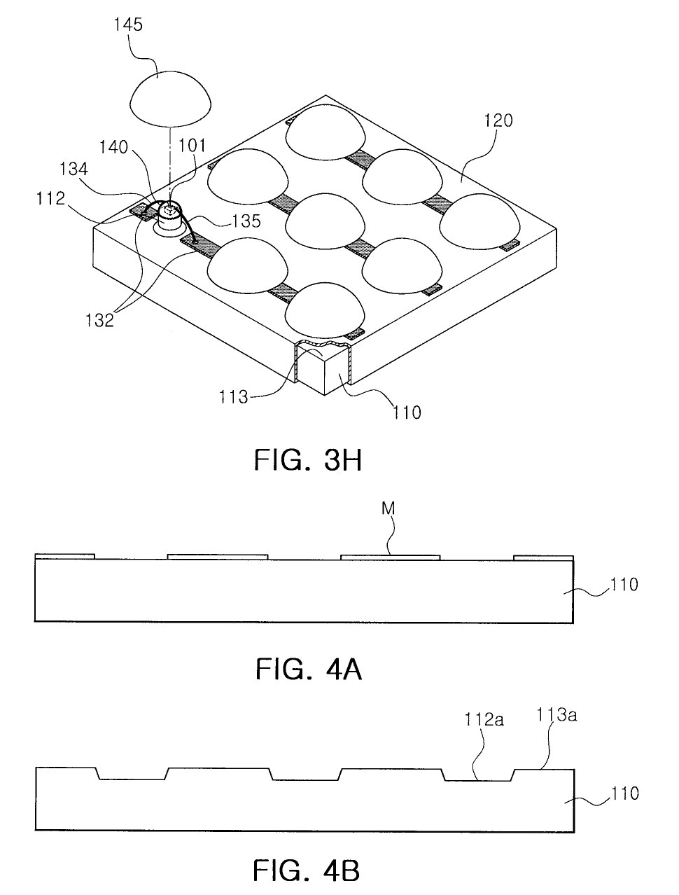

FIGS. 2A to 2I are cross-sectional views illustrating a method of manufacturing a high power LED package according to an exemplary embodiment of the invention. FIGS. 3A to 3H are perspective views illustrating a method of manufacturing a high power LED package according to an exemplary embodiment of the invention.

The high power LED package 100 of the present embodiment is manufactured by following processes of a to e.

a. At Least One Chip Mounting Part and at Least One Via Hole are Formed on a Metal Plate.

As shown in FIGS. 2A to 2C and FIGS. 3A to 3C, a metal plate 110 having a predetermined size is provided thereon with chip mounting parts 112 where light emitting chips 101 are mounted, respectively upon application of a power source and through holes 114 for forming conductive via holes.

As shown in FIG. 2A and FIG. 3A, the metal plate 110 has a mask M of a predetermined size patterned or applied on a top surface thereof to correspond to the chip mounting parts 112.

Subsequently, the top surface of the metal plate 110 is chemically etched. Then, as shown in FIGS. 2B and 3B, portions of the top surface of the metal plate 110 excluding the mask M are uniformly removed to form the chip mounting parts each having a predetermined height greater than a height of each of lower portions 113 of a top surface of the metal plate 110.

Here, as shown, the chip mounting parts 112 are formed by chemical etching but not limited thereto. The top surface of the metal plate 10 excluding portions for the chip mounting parts 112 may be mechanically polished to form the chip mounting parts 112 each having a predetermined height greater than a height of the lower portions 113 of a top surface of the metal plate 110.

Also, as shown in FIGS. 2C and 3C, the metal plate 110 having the chip mounting parts 112 formed thereon has the through holes 114 of a predetermined size formed in the lower portions 113 of a top surface thereof by one of punching, drilling and laser process.

Here, the metal plate 110 having the chip mounting parts 112 and the through holes 114 formed thereon may be formed of a high heat conductivity material selected from copper (Cu), copper alloy (Cu Alloy), aluminum (Al), aluminum alloy (Al Alloy), magnesium (Mg), magnesium alloy (Mg Alloy), titanium (Ti), titanium alloy (Ti Alloy), steel, and stainless steel.

In the present embodiment, the metal plate 110 may be formed of an anodizable metal such as aluminum, aluminum alloy, magnesium (Mg), magnesium alloy (Mg alloy), titanium (Ti), and titanium alloy (Ti alloy).

Meanwhile, as shown in FIGS. 2A to 2C, the metal plate 110 is chemically etched or mechanically polished to form the chip mounting parts 112 thereon. Then, the through holes 114 are formed in the lower portions 113 of a top surface of the metal plate 110 having a smaller height than the top surfaces of the chip mounting parts 112. But the present invention is not limited thereto. Alternatively, the through holes 114 are formed in the top surface of the metal plate 110 and then the metal plate 110 is chemically etched or mechanically polished to form the chip mounting parts 114 thereon.

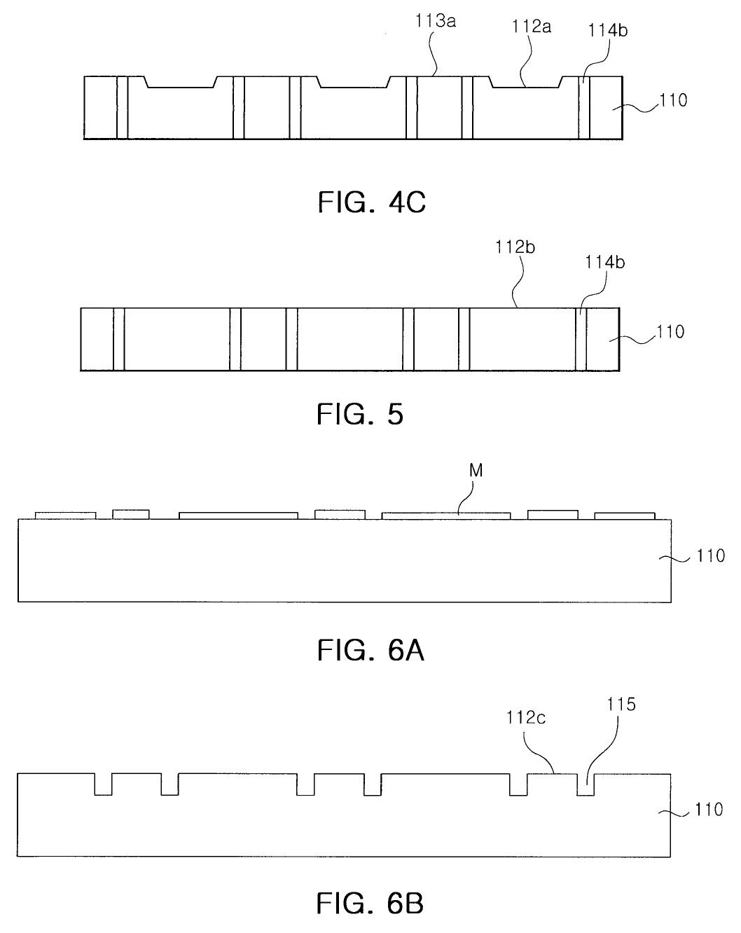

Moreover, to form chip mounting parts 112a and through holes 114a, as shown in FIGS. 4A to 4C, the mask M is formed on the top surface of the metal plate 110 excluding portions for the chip mounting parts 112, and then the top surface of the metal plate 110 is chemically etched or mechanically polished to form the chip mounting parts 112a of a predetermined depth. Subsequently, the through holes 114a may be formed in a top surface 113a of the metal plate 110 having a height greater than a height of each of the chip mounting parts 112a. However, the present invention is not limited thereto. Alternatively, the through holes 114a may be formed in the top surface of the metal plate 110 and the top surface of the metal plate 110 may be chemically etched or mechanically polished to form the chip mounting parts 112a of a predetermined depth.

Furthermore, to form the chip mounting parts 112b and the through holes 114b, as shown in FIG. 5, chip mounting parts 112b are formed co-planar with the top surface of the metal plate 110 where the through holes 114b are formed. Therefore, top ends of the through holes 114b and the chip mounting parts 112b are co-planar with each other.

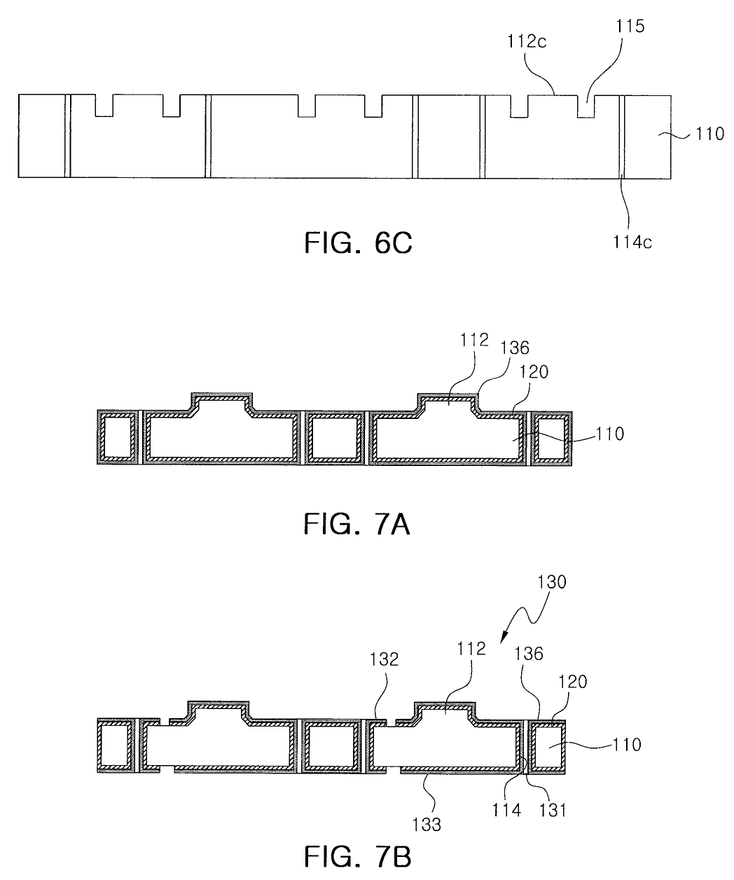

Also, to form the chip mounting part 112c and the through holes 114c, as shown in FIGS. 6A to 6C, a mask M is formed on portions of the top surface of the metal plate 110 where the chip mounting part 112c is to be formed and an electrode part, which will be described later, is to be formed. Then, the top surface of the metal plate 110 is chemically etched or mechanically polished to form a trench 115 of a predetermined depth. Thereafter, the chip mounting part 112c having an outer circumference defined by the trench 115 and the through holes 114c are formed in the top surface of the metal plate 110.

However, the present invention is not limited thereto. First, the through holes 114c may be formed in the top surface of the metal plate 110. Then, the top surface of the metal plate 110 may be chemically etched or mechanically polished to form the trench 115 of a predetermined depth. This allows for formation of the chip mounting part 112c having the outer circumference defined by the trench 11.

b. An Insulating Layer is Formed on an Outer Surface of the Metal Plate.

The metal plate 110 having the chip mounting parts 112 and the through holes 114 formed thereon is immersed in an electrolytic bath filled with electrolyte. Then, an insulating layer 120, i.e., an anodized oxide layer is formed to a predetermined thickness on an entire outer surface of the metal plate 110 including an outer surface and a lower portion of the top surface of each of the chip mounting parts 112 and an inner circumferential surface of each of the through holes.

This insulating layer 120 may be formed to a uniform thickness of 10 μm to 30 μm on the entire outer surface of the metal plate 110.

Here, the through hole 114 has an inner diameter greater than a thickness of the insulating layer 120, thus not blocked by the insulating layer 120 after formation of the insulating layer 120.

That is, in a case where the metal plate 110 is formed of aluminum or aluminum alloy, the insulating layer 120 made of e.g., Al₂O₃ is formed on the outer surface of the metal plate 110. This insulating layer 120 has ceramic characteristics ensuring higher mechanical strength, and is formed of a porous column to allow following processes such as coloring, applying and printing to be performed more stably.

Also, in a case where the metal plate 110 is formed of titanium or titanium alloy, the insulating layer 120 made of e.g., TiO₂ is formed on the outer surface of the metal plate 110. This insulating layer 120 has high reflectivity and thus ensures higher efficiency in reflecting light emitted from the light emitting chips 101, thereby enhancing optical efficiency of the package 100.

Here, the insulating layer 120 is formed on the metal plate 110 by anodizing, but not limited thereto. The insulating layer 120 may be formed by plasma electrolyte oxidation (PEO) or dry oxidation using a high temperature oxidation gas.

Also, the insulating layer 120 is formed of Al₂O₃ or TiO₂ but not limited thereto. The insulating layer 120 may be formed of MgO.

c. An Electrode Part is Formed to Electrically Connect to the Light Emitting Chips Mounted on the Chip Mounting Parts.

Forming an electrode part 130 includes forming conductive via holes 131, forming external electrodes 132 and 133 and electrically connecting the light emitting chips 101 to the external electrodes 132 and 133.

That is, to form the conductive vias 131, as shown in FIGS. 2E and 3E, a conductive material such a conductive paste is filled or applied in the through holes 114 of the metal plate 110 having the insulating layer 120 formed with a predetermined thickness on the outer surface thereof, thereby forming the conductive vias 131 for supplying a power source.

Moreover, to form the external electrodes 132 and 133, as shown in FIGS. 2F and 3F, portions of the insulating layer 120 where the conductive vias 131 are exposed outward are provided with the external electrodes 132 and 133 to be connected to a top end and bottom end of the conductive vias 131, respectively.

Here, since the insulating layer 120 is formed of a highly bondable insulating film, the external electrodes 132 and 133 may be formed by one of a process of printing and sintering a conductive paste, a process of metallizing and plating a surface of the insulating layer and a vacuum deposition process.

Thereafter, to electrically connect the light emitting chips 101 and the external electrodes 132 and 133, as shown in FIGS. 2G and 3G, the light emitting chips 101 are mounted on the chip mounting parts 112 protruded to a predetermined height by an adhesive, respectively. Then each of the light emitting chips 101 is wire-bonded to adjacent ones of the external electrodes 132 formed on the top surface of the metal plate 110 by metal wires 134 and 135, respectively to be electrically connected to each other.

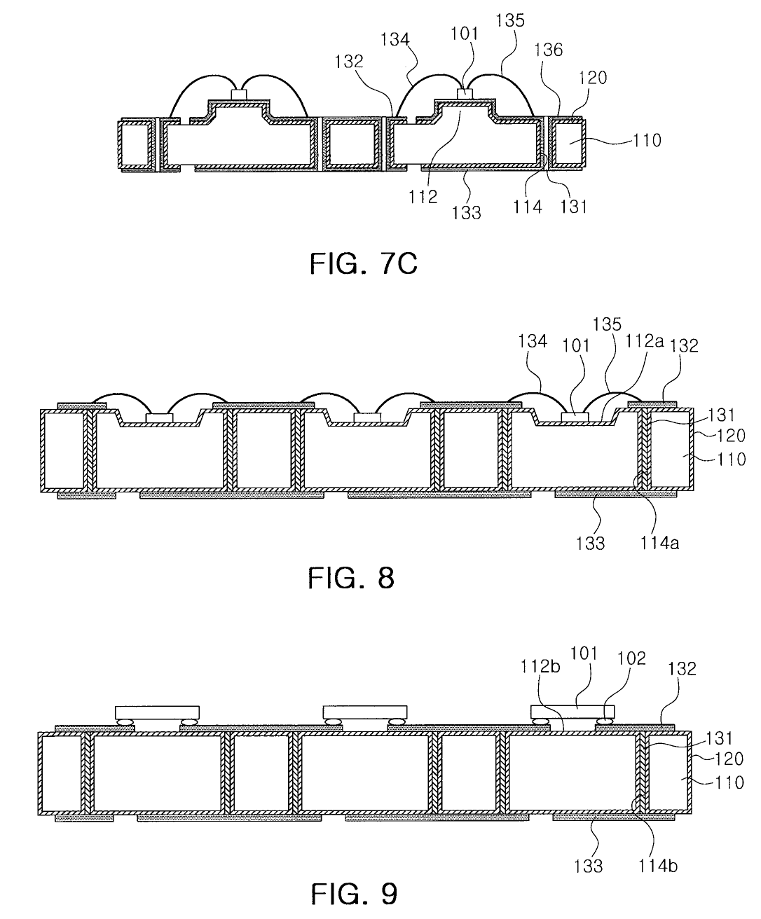

Meanwhile, to form the electrode part 130, as shown in FIGS. 7A and 7B, through conductive via holes 131 and external electrodes 132 and 133 are formed at the same time. Thereafter, the light emitting chips 101 and the external electrodes 132 and 133 are electrically connected together.

That is, to form the through conductive via holes 131, as shown in FIG. 7A, a conductive metal layer 136 of at least a single layer structure is formed with a predetermined thickness on an entire surface of the insulating layer 120.

This metal layer 136 may be formed by deposition using a conductive metal such as palladium (Pd) and zinc (Zn). The metal layer 136 may be formed by plating Ni/Cu and then a metal material such as Ag, but the present invention is not limited thereto. The metal layer 136 may include a metal seed layer formed by deposition and a plating layer disposed on the metal seed layer.

Accordingly, each of the through holes 114 is filled with the conductive material without being blocked and each of the through conductive vias 131 having the insulating layer 120 and the metal layer 135 applied thereon is formed in an inner circumferential surface of the through hole.

Further, to form the external electrodes 132 and 133, as shown in FIG. 7B, out of the entire metal layer 136 formed on the entire outer surface of the insulating layer 120 to be exposed outward, the remaining area of the metal layer 136 excluding a portion corresponding to a predetermined circuit pattern is removed to form the external electrodes 132 and 133 connected to the top end and bottom end of the conductive via 131.

Here, the external electrodes 132 and 133 may be formed by wet etching in which an unnecessary portion of the metal layer is removed using the mask M disposed on the outer surface of the metal layer or dry etching.

Thereafter, to electrically connect the light emitting chips 101 to the external electrodes 132 and 133, as shown in FIG. 7C, each of the light emitting chips 101 is mounted on the chip mounting part 112 protruded to a predetermined height by adhesive. Then, the light emitting chip 101 is wire-bonded to adjacent ones of the external electrodes 132 formed on the top surface of the metal plate 110 by metal wires 134 and 135, respectively to be electrically connected to each other.

Meanwhile, in a case where the chip mounting part 112a is recessed to a predetermined depth from the metal plate 110, the light emitting chip 101 and the external electrodes 132 and 133 are electrically connected together, as shown in FIG. 8. That is, the light emitting chip 101 is mounted on the chip mounting part 112a protruded to a predetermined depth by an adhesive. Then the light emitting chip 101 is wire-bonded to the adjacent ones of the external electrodes 132 formed higher than the chip mounting part 112a by metal wires 134 and 135, respectively to be electrically connected together.

Also, in a case where the chip mounting part 112b is formed co-planar with the metal plate 110, the light emitting chip 101 is electrically connected to the external electrodes 132 and 133, as shown in FIG. 9. That is, the external electrode 132 connected to conductive via 131 formed in the metal plate 110 is extended to the chip mounting part 112b and then the light emitting chip 101 is flip-chip bonded to the external electrode 132 by a solder ball 102 disposed on the external electrode 132 to be electrically connected to each other.

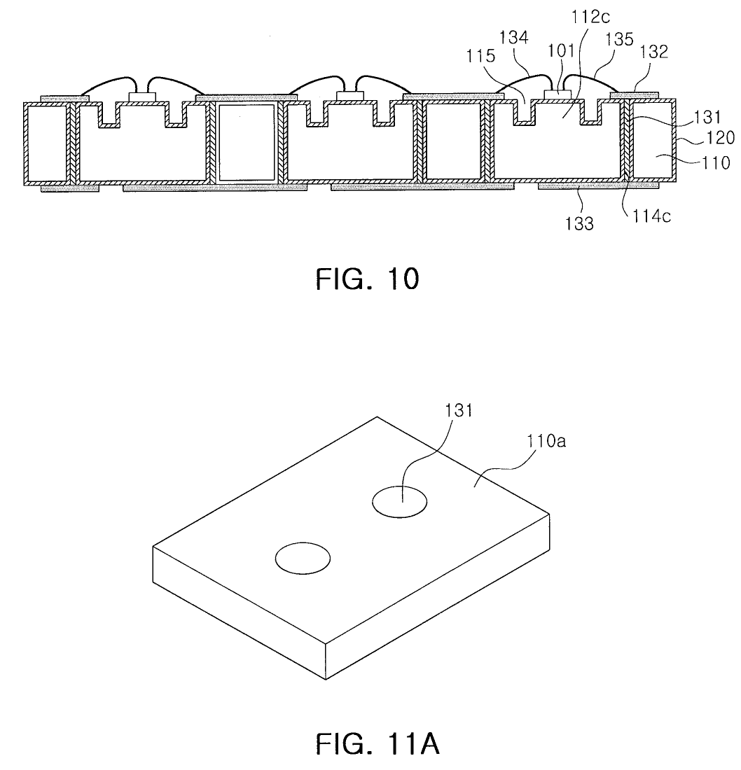

Furthermore, the chip mounting part 112c having an outer circumference defined by the trench 115 recessed to a predetermined depth may be formed co-planar with the metal plate 110. At this time, to electrically connect the light emitting chip 101 to the external electrodes 132 and 133, as shown in FIG. 10, the light emitting chip 101 is mounted on the chip mounting part 112c using an adhesive. Subsequently, the light emitting chip 101 is wire-bonded to the outer electrode 132 formed on the top surface of the metal plate 110 by metal wires 134 and 135 to be electrically connected together.

Here, the external electrodes 133 formed on a bottom of the metal plate 110 are electrically connected to a power source supply pad disposed on an unillustrated substrate. This allows an external power source to be supplied to the light emitting chip 101 through the conductive via hole 131, external electrodes 132 and 133, and metal wires 134 and 135 or the solder ball 102 to emit light.

d. An Encapsulant is Formed on the Top Surface of the Chip Mounting part to encapsulate the light emitting chip;

With the light emitting chip 101 electrically connected to the electrode part 130, as shown in FIGS. 2H and 3H, an encapsulant 140 is formed on the top surface of the chip mounting part 112 to encapsulate the light emitting chip 101.

Here, the encapsulant 140 may contain phosphors to enhance efficiency of light emitted from the light emitting chip 101.

To form the encapsulant 140, after mounting the light emitting chip 101 on the chip mounting part 112, a liquid resin is injected to cover the light emitting device 101 and then cured.

Moreover, when the liquid resin is injected onto the chip mounting part 112 to cover the light emitting device 101, the encapsulant 140 is formed to have an outer side portion curved by surface tension and a central portion domed upward.

Specifically, the liquid resin is injected such that an outer end thereof is located to conform to edges of the top surface of the chip mounting part 112, i.e., knife edges. The outer end of the liquid resin, when positioned on the knife edges of the chip as described above, ensures greater surface tension than a case where the outer end of the liquid resin is positioned on the top surface of the chip mounting part. This prevents the liquid resin from flowing over the knife edges of the chip mounting part 112 and diffusing outside the chip mounting part 112, but allows the liquid resin to be domed upward.

Meanwhile, the lens part 145 is formed on the top surface of the metal plate 110 to cover and protect the light emitting chip 101 wire-bonded to the metal wires 134 and 135 of the electrode part 130, the encapsulant encapsulating the light emitting chip 101 and the metal wires 134 and 135 from external environment. The lens parts 140 are formed of a transparent material.

Each of the lens parts 140 is illustrated to be configured as a convex lens mounted on the top surface of the metal plate 110 to ensure light generated from the light emitting chip 101 to be radiated outward at a wider angle, but the present invention is not limited thereto. The lens part may be formed of a light transmissive transparent resin applied in a dome shape on the top surface of the metal plate 110.

Here, in a case where the lens part 140 is configured as a convex lens, a void between the metal plate 110 and the lens part 140 may be filled with the light transmissive transparent resin containing one phosphor material of AG, TAG, and silicate as a means for converting wavelength. In a case where the lens part is formed of the light transmissive transparent resin, the lens part may further contain the phosphor material.

In the present embodiment, after forming the encapsulant 140 on the chip mounting part 112 to encapsulate the light emitting chip 101, the lens part 145 covering the light emitting chip 101 and the encapsulant 140 as well is formed on the top surface of the metal plate 110. However, the present invention is not limited thereto. Only the lens part 145 may be formed without employing the encapsulant 140.

e. The Metal Plate is Cut Along a Trimming Line to Separate the Package.

When the light emitting chips 101 are mounted on the chip mounting part s112 to be electrically connected to the electrode part 130, and the encapsulant 140 and the lens parts 145 are disposed on the metal plate, as shown in FIG. 2I, the metal plate 110 is cut using an unillustrated cutting device along a virtual trimming line C drawn on the metal plate 110 to complete a high power LED package 100.

Here, as shown in FIGS. 2H and 3H, the trimming line C is located to pass through between one of the conductive via hole 131s and another adjacent conductive via hole 131, and the metal plate is cut along such a trimming line C. Then, as shown in FIG. 11A, the conductive via hole 131 is positioned inside a heat radiator 110a cut to be separated from the metal plate 110.

Also, the trimming line C may be located to pass through a center of the conductive via 131 formed between one of the chip mounting parts 112 and another adjacent chip mounting part 112, and then the metal plate is cut along the trimming line C. As shown in FIG. 11B, this allows the conductive via hole 131 to be positioned at a corner or an edge of the heat radiator 110a cut to be separated from the metal plate 110.

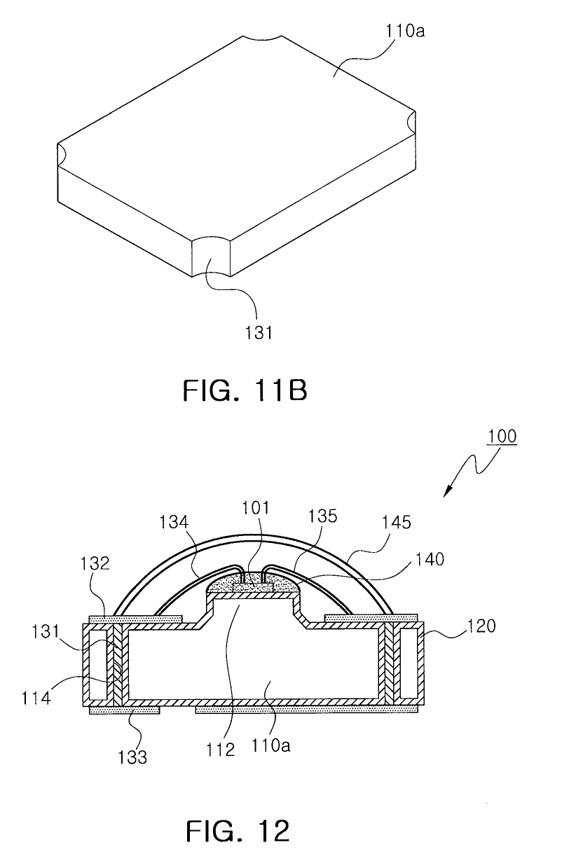

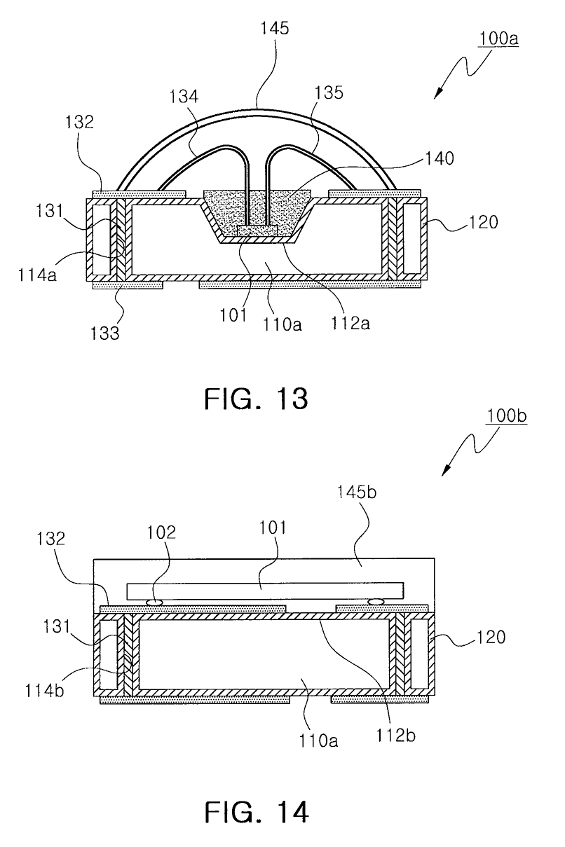

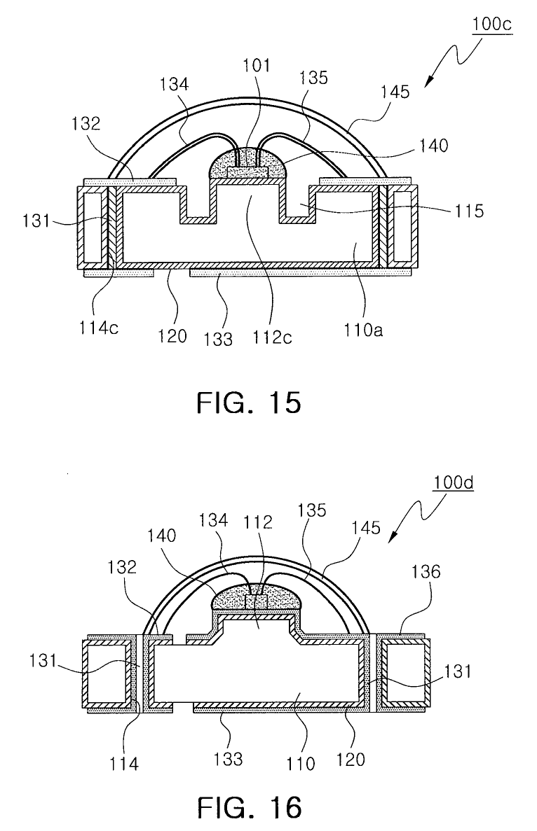

FIG. 12 is a cross-sectional view illustrating a high power LED package according to an exemplary embodiment of the invention. FIG. 13 is a cross-sectional view illustrating a high power LED package according to another exemplary embodiment of the invention. FIG. 14 is a cross-sectional view illustrating a high power LED package according to still another exemplary embodiment of the invention. FIG. 15 is a cross-sectional view illustrating a high power LED package according to a modified embodiment of the invention and FIG. 16 is a cross-sectional view illustrating a high power LED package according to another modified embodiment of the invention.

The packages 100, 100a, 100b and 100c of the present embodiments each include a heat radiator 110a, an insulating layer 120 and an electrode part 130.

The heat radiator 110a is a metal structure including a chip mounting part 112 having a light emitting chip 101 mounted on a top surface thereof and conductive via holes 131.

This heat radiator 110a may be formed of at least one high thermal conductivity material selected from copper (Cu), copper alloy (Cu Alloy), aluminum (Al), aluminum alloy (Al Alloy), magnesium (Mg), magnesium alloy (Mg Alloy), titanium (Ti), titanium alloy (Ti Alloy), steel, and stainless steel.

In the present embodiments, the heat radiator 110a may be formed an anodizable metal material selected from aluminum, aluminum alloy, magnesium (Mg), magnesium alloy (Mg Alloy), titanium (Ti), and titanium alloy (Ti Alloy).

Also, to mount the light emitting chip 101 on the chip mounting part 112, as shown in FIG. 12, the chip mounting part 112 formed on the heat radiator 110a may be partially removed by chemical etching or mechanical polishing, excluding a portion where the light emitting chip 101 is to be mounted, to be protruded upward to a predetermined height.

As shown in FIG. 13, the chip mounting part 112a may have a portion where the light emitting chip 101 is to be mounted partially removed by chemical etching or mechanical polishing to be recessed to a predetermined depth.

Moreover, as shown in FIG. 14, the chip mounting part 112b may be formed of a substrate-type chip mounting part in which a mounting area of the light emitting chip 101 is formed on the top surface of the heat radiator 101 having the external electrodes 132 formed thereon.

Also, as shown in FIG. 15, the chip mounting part 112c may be configured as a trench-type chip mounting part 112c having an outer circumference defined by the trench 115 recessed to a predetermined depth by partially removing the top surface of the heat radiator 101 through chemical etching or mechanical polishing along the mounting area of the light emitting chip 101.

In addition, an insulating layer 120 is applied on inner circumferential surfaces of through holes 114, 114a, 114b and 114c formed in the heat radiator 110a and then conductive via holes 131 each are filled or applied with a conductive material such as a conductive paste to have top and bottom ends thereof exposed to top and bottom surfaces of the heat radiator 110a, respectively.

The insulating layer 120 is an insulating member formed with a predetermined thickness on an outer surface of the heat radiator 110a and inner surfaces of the through holes 114, 114a, 114b, and 114c.

This insulating layer 120 may have a uniform thickness of 10 μm to 30 μm. Each of the through holes 114, 114a, 114b, and 114c has an inner diameter greater than a thickness of the insulating layer 120, thus not blocked by the insulating layer 120 after formation of the insulating layer 120.

The metal plate 110 where the chip mounting part 112, 112a, 112b, and 112c and the through hole 114, 114a, 114b, and 114c are formed therein is immersed in an electrolytic bath filled with electrolyte. Then the insulating layer 120, i.e., anodized layer is formed with a predetermined thickness on an entire outer surface of the metal plate 110 including an outer surface and a lower portion of the top surface of the chip mounting part 112, 112a, 112b and 112c, and an inner circumferential surface of the through hole by an anodizing process.

This insulating layer 120 may be formed on the entire outer surface of the metal plate 110 to have a uniform thickness of 10 μm to 30 μm.

Here, the through hole 114, 114a, 114b, and 114c has an inner diameter greater than a thickness of the insulating layer 120 so as to be constantly open without being blocked by the insulating layer 120.

Also, the insulating layer 120 is formed differently according to type of a metal material for the heat radiator 110a. In a case where the heat radiator 110a is formed of aluminum or aluminum alloy, the insulating layer 120 made of e.g., Al₂O₃ may be formed on the outer surface of the heat radiator 110a. Meanwhile, in a case where the heat radiator 110a is formed of titanium or titanium alloy, the insulating layer 120 made of e.g., TiO₂ may be formed on the outer surface of the metal plate 110, but the present invention is not limited thereto. The insulating layer may be formed of an oxide layer made of e.g., MgO.

At this time, the insulating layer 120 made of e.g., TiO₂ has high reflectivity. Thus, by increasing efficiency in reflecting light emitted from the light emitting chip 101, the package may be increased in optical efficiency.

The insulating layer 120 is formed on the heat radiator 110a by one of anodizing, plasma electrolyte oxidation (PEO), and dry oxidation using a high temperature oxidation gas.

Meanwhile, the electrode part 130 electrically connects the conductive via holes 131 formed in the heat radiator 110a to the light emitting chip 101 formed on the chip mounting part 112, 112a, 112b, and 112c.

Each of the conductive via holes 131 has external electrodes 132 and 133 formed thereon to allow the light emitting chip 101 to be wire-bonded or flip chip bonded to the external electrodes 132 and 133 and to ensure electrical connection with an external power source.

These external electrodes 132 and 133 may be formed by one of a process of printing and sintering a conductive paste to electrically connect to top and bottom ends of the conductive via hole 131 exposed outward from the insulating layer 120, a process of metallizing and plating a surface of the insulating layer, and a vacuum deposition process.

Accordingly, the external electrodes 132 formed on the top surface of the heat radiator 110a, as shown in FIG. 12, can be wire-bonded to the light emitting chip 101 mounted on the chip mounting part 112 protruded upward to a predetermined height by metal wires 134 and 135, respectively.

Furthermore, as shown in FIG. 13, the external electrodes 132 formed on the top surface of the heat radiator 11a may be wire-bonded to the light emitting chip 101 mounted on the chip mounting part 112a recessed downward to a predetermined depth by the metal wire 134 and 135, respectively.

Also, as shown in FIG. 14, the external electrodes 132 formed on the top surface of the heat radiator 110a may be flip-chip bonded to the light emitting chip 101 mounted on the chip mounting part 112b formed co-planer with the heat radiator 110a having the external electrode 132 formed thereon by a solder ball 101.

Also, as described in FIG. 15, the outer electrode 132 formed on the top surface of the heat radiator 110a may be wire-bonded to the light emitting chip 101 having an outer circumference defined by the trench 115 recessed to a predetermined depth, by metal wires 134 and 135.

Moreover, as shown in FIGS. 12 to 15, the external electrodes 132 formed on the top surface of the heat radiator 110a are directly formed on the outer surface of the insulating layer 120, but the present invention is not limited thereto.

That is, as shown in FIG. 16, a conductive metal layer 136 of at least a single layer structure may be formed on an entire surface of the insulating layer 120 to have a predetermined thickness by vacuum deposition or plating. This allows the through conductive via hole 131 having the insulating layer 120 and the metal layer 136 applied in multiple layers to be formed in an inner circumferential surface of the through hole 114.

Subsequently, the metal layer 135 formed on the entire surface of the insulating layer 120 to be exposed outward is partially removed by wet etching or dry etching, excluding a predetermined portion for circuit pattern, thereby forming patterns of the external electrodes 132 and 133 to connect to the top and bottom ends of the conductive via hole 131, respectively.

Accordingly, in the same manner as described above, the external electrodes formed on the top surface of the heat radiator 110a are wire bonded to the light emitting chip 101 mounted on the chip mounting part 112a by metal wires 134 and 135, respectively.

Also, the external electrodes 133 formed on the bottom of the heat radiator 110a are electrically connected to the power source supply pad formed on the unillustrated substrate.

Here, the conductive via hole 131 electrically connected to the external electrodes 132 and 133 may be formed of an inner type or an outer type depending on the trimming line for cutting the metal plate. As shown in FIG. 11A, this conductive via hole 131 may be formed of an inner type to be located inside the heat radiator 110a. Alternatively, as shown in FIG. 11B, the conductive via hole 131 may be formed of an outer type to be located at a corner or an edge of the heat radiator 110a.

Meanwhile, with the light emitting chip 101 and the electrode part 130 electrically connected together, an encapsulant 140 is formed on the top surface of the mounting part to encapsulate the light emitting chip 101. Here, the encapsulant 140 may contain phosphors to enhance efficiency of light emitted from the light emitting chip 101.

As shown in FIGS. 12, 13, 15 and 16, a lens part 145 is provided on the top surface of the heat radiator 110a to protect the light emitting chip 101, the encapsulant 140 and the metal wires 134 and 135 from external environment. The lens part 145 is formed of a transparent material.

This lens part 145 may be disposed in a convex lens on the top surface of the heat radiator 110a or a light transmissive transparent resin applied in a dome shape on the top surface of the heat radiator 110a.

Moreover, as shown in FIG. 14, the lens part 145b may be formed of a transparent molding part using a transparent light transmissive rein to protect the light emitting chip 101 flip-chip bonded to the chip mounting part 112b from external environment.

As set forth above, according to exemplary embodiments of the invention, a heat radiator is made of a metal material with high thermal conductivity to easily radiate heat generated from the light emitting chip outward, thereby assuring stable heat radiation properties in a high temperature atmosphere.

Moreover, the chip mounting part is protruded to a predetermined height from the heat radiator to allow the light emitting chip to be mounted higher than a top surface of the heat radiator. This minimizes optical loss when light is emitted and increases luminosity to enhance optical properties.

Also, the manufacturing method precludes a need for a conventional injection molding process. This enables minimal spacings between packages, thereby allowing the LED package to be mounted with a higher density. This also simplifies the manufacturing and assembly processes to realize mass production and saves manufacturing costs.

In addition, the package can be increased in mechanical strength due to an insulating layer formed on an outer surface of a heat radiator. The light emitting chip can be electrically connected to external electrodes stably to improve product reliability.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a high-power light emitting diode package, the method comprising:
forming at least one chip mounting part and at least one through hole in a metal plate;
forming an insulating layer of a predetermined thickness on an entire outer surface of the metal plate; and
forming an electrode part to be electrically connected to a light emitting chip mounted on the chip mounting part.

2. The method of claim 1, wherein the forming at least one chip mounting part and at least one through hole comprises forming the chip mounting part of a predetermined height by chemically etching or mechanically polishing a top surface of the metal plate and then forming the through hole in a lower portion of the top surface of the metal plate having a height smaller than a height of the chip mounting part.

3. The method of claim 1, wherein the forming at least one chip mounting part and at least one through hole comprises forming the through hole in a top surface of the metal plate and then forming the chip mounting part of a predetermined height by chemically etching or mechanically polishing the top surface of the metal plate.

4. The method of claim 1, wherein the forming at least one chip mounting part and at least one through hole comprises forming the chip mounting part of a predetermined depth by chemically etching or mechanically polishing a top surface of the metal plate and then forming the through hole in the top surface of the metal plate having a height greater than a height of the chip mounting part.

5. The method of claim 1, wherein the forming at least one chip mounting part and at least one through hole comprises forming the through hole in a top surface of the metal plate and then forming the chip mounting part of a predetermined depth by chemically etching or mechanically polishing the top surface of the metal plate.

6. The method of claim 1, wherein the forming at least one chip mounting part and at least one through hole comprises forming the chip mounting part on a top surface of the metal plate where the through hole is formed.

7. The method of claim 1, wherein the forming at least one chip mounting part and at least one through hole comprises forming a trench of a predetermined depth by chemically etching or mechanically polishing a top surface of the metal plate to form the chip mounting part having an outer circumference defined by the trench.

8. The method of claim 1, wherein the forming at least one chip mounting part and at least one through hole comprises forming the through hole on a top surface of the metal plate and forming a trench of a predetermined depth by chemically etching or mechanically polishing the top surface of the metal plate to form the chip mounting part having an outer circumference defined by the trench.

9. The method of claim 1, wherein the metal plate is formed of an anodizable metal.

10. The method of claim 1, wherein the metal plate is formed of one of aluminum, aluminum alloy, magnesium, magnesium alloy, titanium, and titanium alloy.

11. The method of claim 1, wherein the insulating layer is formed by one of anodizing, plasma electrolyte oxidation, and dry oxidation.

12. The method of claim 1, wherein the insulating layer is formed of one of Al₂O₃, TiO₂, and MgO.

13. The method of claim 1, wherein the forming an electrode part comprises:
forming a conductive via by filling or applying a conductive material in the through hole having the insulating layer applied on an inner circumferential surface thereof;
forming external electrodes to connect to a top end and bottom end of the conductive vias exposed outward from the insulating layer, respectively; and
electrically connecting the light emitting chip mounted on the chip mounting part to the external electrodes, respectively.

14. The method of claim 1, wherein the forming an electrode part comprises:
forming a metal layer of at least a single layer structure on an entire outer surface of the insulating layer and forming a conductive through via hole;
forming external electrodes to connect to a top end and bottom end of the conductive through via hole, respectively by partially removing the metal layer; and
electrically connecting the light emitting chip mounted on the chip mounting part to the external electrodes, respectively.

15. The method of claim 13, wherein the electrically connecting the light emitting chip to the external electrodes comprises wire-bonding the light emitting chip mounted on the chip mounting part protruded to a predetermined height from a top surface of the metal plate to the external electrodes by metal wires.

16. The method of claim 13, wherein the electrically connecting the light emitting chip to the external electrodes comprises wire-bonding the light emitting chip mounted on the chip mounting part recessed to a predetermined depth from a top surface of the metal plate to the external electrodes by metal wires.

17. The method of claim 13, wherein the electrically connecting the light emitting chip to the external electrodes comprises flip-chip bonding the light emitting chip to the external electrodes extended to the chip mounting part.

18. The method of claim 13, wherein the electrically connecting the light emitting chip to the external electrodes comprises wire-bonding the light emitting chip to the external electrodes by a metal wire, the light emitting chip mounted on the chip mounting part having an outer circumference defined by a trench recessed to a predetermined height from a top surface of the metal plate.

19. The method of claim 13, wherein the external electrodes are formed by one of a process of printing and sintering a conductive paste, a process of metallizing and plating a surface of the insulating layer and a vacuum deposition process.

20. The method of claim 1, further comprising forming an encapsulant containing a phosphor on a top surface of the chip mounting part to encapsulate the light emitting chip.

21. The method of claim 20, wherein the forming an encapsulant comprises forming a lens part or a molding part for protecting the light emitting chip, the encapsulant encapsulating the light emitting chip and a portion of the electrode part electrically connected to the light emitting chip from external environment.

22. The method of claim 1, further comprising forming a lens part or a molding part on a top surface of the metal plate to protect the light emitting chip from external environment, the lens part or the molding part formed of a transparent material.

23. The method of claim 1, further comprising cutting the metal plate along a trimming line to separate the package.

24. The method of claim 23, wherein the cutting the metal plate comprises cutting the metal plate along the trimming line passing through a portion between one conductive via hole and another adjacent conductive via hole.

25. The method of claim 23, wherein the chip mounting part comprises a plurality of chip mounting parts, and the cutting the metal plate comprises cutting the metal plate along the trimming line passing through a center of a conductive via hole formed between one of the chip mounting parts and another adjacent chip mounting part.

26. A high power light emitting diode package comprising:
a heat radiator comprising a chip mounting part having at least one light emitting chip mounted thereon and at least one conductive via hole;
an insulating layer formed with a predetermined thickness on an outer surface of the heat radiator; and
an electrode part electrically connecting the conductive via hole and the light emitting chip.

27. The high power light emitting diode package of claim 26, wherein the heat radiator is formed of an anodizable metal.

28. The high power light emitting diode package of claim 26, wherein the heat radiator is formed of one of aluminum, aluminum alloy, magnesium, magnesium alloy, titanium, and titanium alloy.

29. The high power light emitting diode package of claim 26, wherein the chip mounting part comprises one of a protrusion type chip mounting part protruded to a predetermined height from a top surface of the heat radiator, a recession type chip mounting part recessed to a predetermined depth from the top surface of the heat radiator, a substrate type chip mounting part disposed on the top surface of the heat radiator and a trench type chip mounting part recessed to a predetermined depth from the top surface of the heat radiator.

30. The high power light emitting diode package of claim 26, wherein the insulating layer is formed with a predetermined thickness on an outer surface of the heat radiator by one of anodizing, plasma electrolyte oxidation, and dry oxidation.

31. The high power light emitting diode package of claim 26, wherein the insulating layer is formed of one of Al₂O₃, TiO₂, and MgO.

32. The high power light emitting diode package of claim 26, wherein the electrode part comprises:
a conductive via hole formed by filling or applying a conductive material in the through hole having the insulating layer applied on an inner circumferential surface thereof;
external electrodes formed on the insulating layer to connect to a top end and bottom end of the conductive via hole, respectively; and
a metal wire wire-bonding the light emitting diode chip to the external electrodes.

33. The high power light emitting diode package of claim 26, wherein the electrode part comprises:
a conductive via hole formed by filling or applying a conductive material in the through hole having the insulating layer applied on an inner circumferential surface thereof;
external electrodes formed on the insulating layer to connect to a top end and bottom end of the conductive via hole, respectively; and
a solder ball flip-chip bonding the light emitting chip to the external electrodes.

34. The high power light emitting diode package of claim 26, wherein the electrode part comprises:
a conductive via hole formed by filling or applying a conductive material in the through hole having the insulating layer applied on an inner circumferential surface thereof;
external electrodes formed by partially removing a metal layer of at least a single layer structure applied on an entire outer surface of the insulating layer to connect to a top end and bottom end of the conductive via hole, respectively; and
a metal wire wire-bonding the light emitting diode chip to the external electrodes.

35. The high power light emitting diode package of claim 26, wherein the electrode part comprises:
a conductive via hole formed by filling or applying a conductive material in the through hole having the insulating layer applied on an inner circumferential surface thereof;
external electrodes formed by partially removing a metal layer of at least a single layer structure applied on an entire outer surface of the insulating layer to connect to a top end and bottom end of the conductive via hole, respectively; and
a solder ball flip-chip bonding the light emitting chip to the external electrodes.

36. The high power light emitting diode package of claim 26, wherein the conductive via hole is formed in one of an inner portion, a corner and an edge of the heat radiator.

37. The high power light emitting diode package of claim 26, wherein the heat radiator further comprises a lens part or a molding part formed of a transparent material to protect the light emitting chip from external environment.

38. The high power light emitting diode package of claim 26, wherein the heat radiator comprises:
an encapsulant formed on the chip mounting part to encapsulate the light emitting chip; and
a lens part or a molding part formed of a transparent material and protecting the light emitting chip, the encapsulant and a portion of the electrode part from external environment.
